(19) United States
(12) Patent Application Publication
(10) Pub. No.: US 2025/0221010 A1
(43) Pub. Date: Jul. 3, 2025

(54) SEMICONDUCTOR DEVICE AND MANUFACTURING METHOD THEREOF

(71) Applicant: UNITED MICROELECTRONICS CORP., Hsin-Chu City (TW)

(72) Inventors: Yu-Hsuan Lin, New Taipei City (TW); Chuan-Chang Wu, Kaohsiung City (TW); Shih-Hao Liang, Tainan City (TW); Tsung-Hsun Wu, Kaohsiung City (TW); Chih-Kai Kang, Tainan City (TW); Pin Tsao, Tainan City (TW); Sheng-Yuan Hsueh, Tainan City (TW)

(73) Assignee: UNITED MICROELECTRONICS CORP., Hsin-Chu City (TW)

(21) Appl. No.: 18/424,876

(22) Filed: Jan. 29, 2024

(30) Foreign Application Priority Data
Dec. 28, 2023 (TW) 112151344

(51) Int. Cl. H01L 29/51; H01L 27/088; H01L 29/423; H01L 29/66; H01L 29/78; H10B 10/00

(52) U.S. Cl. CPC H10D 64/691; H10B 10/18; H10D 30/021; H10D 30/60; H10D 64/513; H10D 84/83

(57) ABSTRACT

A semiconductor device includes a semiconductor substrate, a first n-type transistor, and a second n-type transistor. The semiconductor substrate has a logic region and a memory region. The first n-type transistor is disposed on the logic region and includes a first gate structure. The second n-type transistor is disposed on the memory region and includes a second gate structure. The first gate structure includes a first tantalum nitride barrier layer and a first n-type work function layer disposed on the first tantalum nitride barrier layer. The second gate structure includes a second tantalum nitride barrier layer and a second n-type work function layer disposed on the second tantalum nitride barrier layer. A thickness of the first tantalum nitride barrier layer is less than a thickness of the second tantalum nitride barrier layer.

### BACKGROUND OF THE INVENTION

### 1. Field of the Invention

The present invention relates to a semiconductor device and a manufacturing method thereof, and more particularly, to a semiconductor device including a tantalum nitride barrier layer and a manufacturing method thereof.

### 2. Description of the Prior Art

In the integrated circuits, transistors may be different from one another in structure for different operation voltages. For example, the transistors for relatively low operation voltage may be applied in core devices, input/output (I/O) devices, and so on. The transistors capable of high voltage processing may be applied in high operation voltage environment such as CPU power supply, power management system, AC/DC converter, and high-power or power amplifier. In addition, the threshold voltages of the transistors in some circuit structures are different from one another, and how to improve the operation performance of different transistors and/or integrate manufacturing processes for transistors with different specifications through the design of structure and/or the design of the manufacturing process is a continuous issue for those in the related fields.

### SUMMARY OF THE INVENTION

A semiconductor device and a manufacturing method thereof are provided in the present invention. A thickness of a tantalum nitride barrier layer of an n-type transistor in a logic region is different from that of a tantalum nitride barrier layer of an n-type transistor in a memory region for satisfying the threshold voltage specification of each n-type transistor.

According to an embodiment of the present invention, a semiconductor device is provided. The semiconductor device includes a semiconductor substrate, a first n-type transistor, and a second n-type transistor. The semiconductor substrate has a logic region and a memory region. The first n-type transistor is disposed on the logic region and includes a first gate structure. The second n-type transistor is disposed on the memory region and includes a second gate structure. The first gate structure includes a first tantalum nitride barrier layer and a first n-type work function layer, and the first n-type work function layer is disposed on the first tantalum nitride barrier layer. The second gate structure includes a second tantalum nitride barrier layer and a second n-type work function layer, and the second n-type work function layer is disposed on the second tantalum nitride barrier layer. A thickness of the first tantalum nitride barrier layer is less than a thickness of the second tantalum nitride barrier layer.

According to an embodiment of the present invention, a manufacturing method of a semiconductor device is provided. The manufacturing method includes the following steps. A semiconductor substrate is provided, and the semiconductor substrate has a logic region and a memory region. A first n-type transistor is formed on the logic region, and a second n-type transistor is formed on the memory region. The first n-type transistor includes a first gate structure, the first gate structure includes a first tantalum nitride barrier layer and a first n-type work function layer, and the first n-type work function layer is disposed on the first tantalum nitride barrier layer. The second n-type transistor includes a second gate structure, the second gate structure includes a second tantalum nitride barrier layer and a second n-type work function layer, and the second n-type work function layer is disposed on the second tantalum nitride barrier layer. A thickness of the first tantalum nitride barrier layer is less than a thickness of the second tantalum nitride barrier layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor device according to an embodiment of the present invention.

FIG. 2 is a top view schematic drawing illustrating a static random access memory structure according to an embodiment of the present invention.

FIG. 3 is a schematic circuit diagram of a static random access memory structure according to an embodiment of the present invention.

FIGS. 4-12 are schematic drawings illustrating a manufacturing method of a semiconductor device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

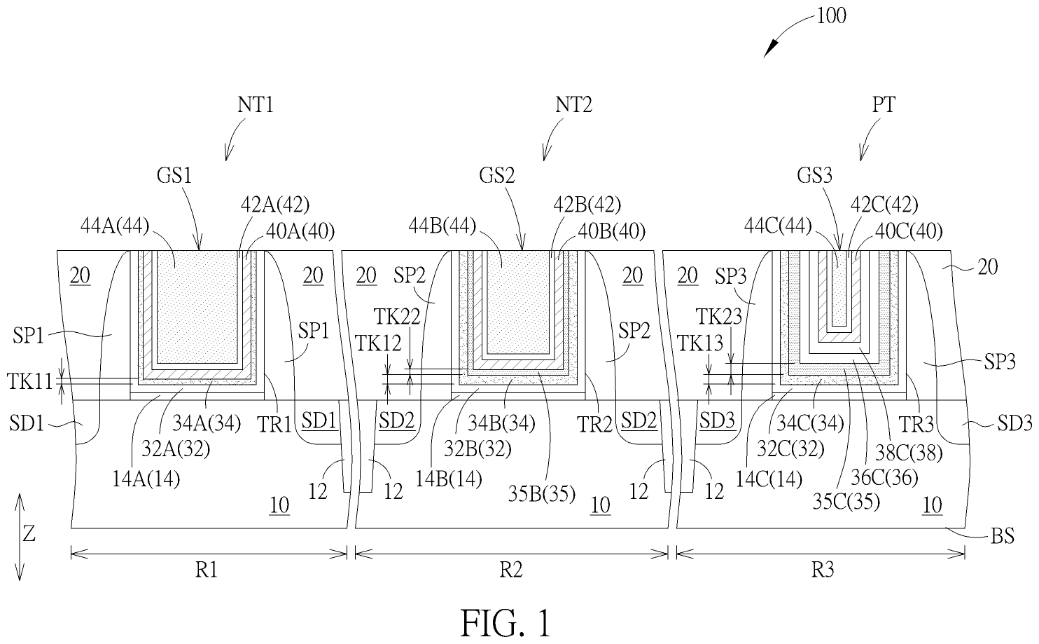

Please refer to FIG. 1. FIG. 1 is a schematic drawing illustrating a semiconductor device 100 according to an embodiment of the present invention. As shown in FIG. 1, the semiconductor device 100 includes a semiconductor substrate 10, a first n-type transistor (such as an n-type transistor NT1), and a second n-type transistor (such as an n-type transistor NT2). The semiconductor substrate 10 has a logic region (such as a first region R1) and a memory region (such as a second region R2). The n-type transistor NT1 is disposed on the first region R1, and the n-type transistor NT2 is disposed on the second region R2. The n-type transistor NT1 includes a first gate structure (such as a gate structure GS1), and the n-type transistor NT2 includes a second gate structure (such as a gate structure GS2). The gate structure GS1 includes a first tantalum nitride barrier layer (such as a tantalum nitride barrier layer 34A) and a first n-type work function layer (such as an n-type work function layer 40A), and the n-type work function layer 40A is disposed on the tantalum nitride barrier layer 34A. The gate structure GS2 includes a second tantalum nitride barrier layer (such as a tantalum nitride barrier layer 34B) and a second n-type work function layer (such as an n-type work function layer 40B), the n-type work function layer 40B is disposed on the tantalum nitride barrier layer 34B, and a thickness TK11 of the tantalum nitride barrier layer 34A is less than a thickness TK12 of the tantalum nitride barrier layer 34B. In this embodiment, the thickness of the tantalum nitride barrier layer in the n-type transistor located on the logic region may be different from the thickness of the tantalum nitride barrier layer in the n-type transistor located on the memory region for matching the threshold voltage specification of each n-type transistor and avoiding negative influence cause by other approaches for adjusting threshold voltage. For example, the thinner tantalum nitride barrier layer 34A may be used to reduce the threshold voltage of the n-type transistor NT1, other treatments for adjusting threshold voltage (such as an ion implantation process for adjusting threshold voltage, but not limited thereto) will not be required to be performed to the n-type transistor NT1 and/or the n-type transistor NT2 accordingly, and the electrical performance of the n-type transistor NT1 and the n-type transistor NT2 may be improved by avoiding negative influence cause by the other treatments.

Specifically, the semiconductor substrate 10 may have a top surface and a bottom surface BS opposite to the top surface in a vertical direction Z, the vertical direction Z may be regarded as a thickness direction of the semiconductor substrate 10, and the gate structure GS1 and the gate structure GS2 described above may be disposed at the side of the top surface. Horizontal directions substantially orthogonal to the vertical direction Z may be substantially parallel with the top surface and/or the bottom surface BS of the semiconductor substrate 10, but not limited thereto. In this description, a distance between the bottom surface BS of the semiconductor substrate 10 and a relatively higher location and/or a relatively higher part in the vertical direction Z may be greater than a distance between the bottom surface BS of the semiconductor substrate 10 and a relatively lower location and/or a relatively lower part in the vertical direction Z. The bottom or a lower portion of each component may be closer to the bottom surface BS of the semiconductor substrate 10 in the vertical direction Z than the top or upper portion of this component. Another component disposed above a specific component may be regarded as being relatively far from the bottom surface BS of the semiconductor substrate 10 in the vertical direction Z, and another component disposed under a specific component may be regarded as being relatively close to the bottom surface BS of the semiconductor substrate 10 in the vertical direction Z. It is worth noting that, in this description, a top surface of a specific component may include the topmost surface of this component in the vertical direction Z, and a bottom surface of a specific component may include the bottommost surface of this component in the vertical direction Z, but not limited thereto. Additionally, in this description, the condition that a certain component is disposed between two other components in a specific direction may include a condition that the certain component is sandwiched between the two other components in the specific direction.

In some embodiments, the semiconductor substrate 10 may include a silicon substrate, an epitaxial silicon substrate, a silicon germanium substrate, a silicon carbide substrate, or a silicon-on-insulator (SOI) substrate, but not limited thereto. In addition, the semiconductor device 100 may further include an isolation structure 12 disposed in the semiconductor substrate 10 for isolating active regions corresponding to different transistors in the semiconductor substrate 10, and the isolation structure 12 may include a single layer or multiple layers of insulation materials, such as an oxide insulation material (e.g. silicon oxide) or other suitable insulation materials. In some embodiments, the semiconductor device 100 may further include a p-type transistor PT disposed on the semiconductor substrate 10, such as being disposed on a third region R3 of the semiconductor substrate, and the third region R3 may be a logic region, a memory region, or other specific device regions. The p-type transistor PT may include a third gate structure (such as a gate structure GS3), and the gate structure GS3 includes a third tantalum nitride barrier layer (such as a tantalum nitride barrier layer 34C), and a p-type work function layer (such as a p-type work function layer 36C and/or a p-type work function layer 38C) disposed on the tantalum nitride barrier layer 34C. In some embodiments, the tantalum nitride barrier layer 34A, the tantalum nitride barrier layer 34B, and the tantalum nitride barrier layer 34C may be made of the same material (such as a tantalum nitride barrier material 34), a thickness TK13 of the tantalum nitride barrier layer 34C may be is greater than the thickness TK11 of the tantalum nitride barrier layer 34A, and the thickness TK13 of the tantalum nitride barrier layer 34C may be substantially equal to the thickness TK12 of the tantalum nitride barrier layer 34B, but not limited thereto.

In some embodiments, the n-type transistor NT1, the n-type transistor NT2, and the p-type transistor PT may include a spacer structure SP1 disposed on the sidewall of the gate structure GS1, a spacer structure SP2 disposed on the sidewall of the gate structure GS2, and a spacer structure SP3 disposed on the sidewall of the gate structure GS3, respectively, and the semiconductor device 100 may further include a dielectric layer 20 disposed on the semiconductor substrate 10 and surrounding each spacer structure and each gate structure in the horizontal directions. In some embodiments, the gate structure GS1 may be regarded as a gate structure disposed in a first trench (such as a trench TR1) surrounded by the spacer structure SP1, the gate structure GS2 may be regarded as a gate structure disposed in a second trench (such as a trench TR2) surrounded by the spacer structure SP2, and the gate structure GS3 may be regarded as a gate structure disposed in a third trench (such as a trench TR3) surrounded by the spacer structure SP3, but not limited thereto. Each of the spacer structures described above may include a single layer or multiple layers of insulations materials, such as an oxide insulation material, a nitride insulation material, or other suitable insulation materials, and the material compositions of the spacer structures may be identical to or different from one another. The dielectric layer 20 may include a single layer or multiple layers of dielectric materials. For example, the dielectric layer 20 may include an etching stop layer and a dielectric material disposed on the etching stop layer, and a material composition of the dielectric material is different from that of the etching stop layer, but not limited thereto.

In some embodiments, the n-type transistor NT1, the n-type transistor NT2, and the p-type transistor PT may include source/drain regions SD1, source/drain regions SD2, and source/drain regions SD3 disposed in the semiconductor substrate 10, respectively. Each source/drain region may be a doped region formed in the semiconductor substrate 10 by a doping process (such as an implantation process), and the dopant type and/or the doping condition of each doped region may be adjusted according to the type of the corresponding transistor structure or other design considerations. In some embodiments, the n-type transistor NT1, the n-type transistor NT2, and the p-type transistor PT may include a gate dielectric layer 14A, a gate dielectric layer 14B, and a gate dielectric layer 14C, respectively, each gate dielectric layer may include a high dielectric constant (high-k) dielectric material or other suitable dielectric materials, and the gate dielectric layers may be made of the same material (such as a dielectric material 14) or made of different dielectric materials according to some design considerations. In some embodiments, the n-type transistor NT1, the n-type transistor NT2, and the p-type transistor PT may include a titanium nitride barrier layer 32A, a titanium nitride barrier layer 32B, and a titanium nitride barrier layer 32C, respectively. Each of the titanium nitride barrier layers may be sandwiched between the corresponding tantalum nitride barrier layer and the corresponding gate dielectric layer in the vertical direction Z, and each of the titanium nitride barrier layers may be sandwiched between the corresponding tantalum nitride barrier layer and the corresponding spacer structure in the horizontal direction. In some embodiments, the titanium nitride barrier layer 32A, the titanium nitride barrier layer 32B, and the titanium nitride barrier layer 32C may be made of the same material (such as titanium nitride barrier material 32), and the thicknesses of the titanium nitride barrier layer 32A, the titanium nitride barrier layer 32B, and the titanium nitride barrier layer 32C may be substantially equal to one another, but not limited thereto. It is worth noting that, some of the layers stacked in each gate structure may have an U-shaped structure in the cross-sectional view of the semiconductor device, and the thickness of the layer in this description may be regarded as the thickness of the center portion in the bottom of the U-shaped structure in the vertical direction Z, but not limited thereto.

In some embodiments, the tantalum nitride barrier layer 34A, the tantalum nitride barrier layer 34B, and the tantalum nitride barrier layer 34C may be mainly composed of tantalum nitride; the titanium nitride barrier layer 32A, the titanium nitride barrier layer 32B, and the titanium nitride barrier layer 32C may be mainly composed of titanium nitride; and the tantalum nitride barrier layer 34A, the tantalum nitride barrier layer 34B, and the tantalum nitride barrier layer 34C may directly contact the titanium nitride barrier layer 32A, the titanium nitride barrier layer 32B, and the titanium nitride barrier layer 32C, respectively, but not limited thereto. In some embodiments, the gate structure GS2 may further include a first mixed layer (such as a mixed layer 35B) disposed between the tantalum nitride barrier layer 34B and the n-type work function layer 40B, the gate structure GS3 may further include a second mixed layer (such as a mixed layer 35C) disposed between the tantalum nitride barrier layer 34C and the p-type work function layer 36 and a third a third n-type work function layer (such as an n-type work function layer 40C) disposed on the p-type work function layer 36C and the p-type work function layer 38C. The mixed layer 35B may be sandwiched between and directly contact the tantalum nitride barrier layer 34B and the n-type work function layer 40B, and the mixed layer 35C may be sandwiched between and directly contact the tantalum nitride barrier layer 34C and the p-type work function layer 36C. In some embodiments, the material composition of the mixed layer 35B may be identical to the material composition of the mixed layer 35C, and a thickness TK23 of the mixed layer 35C may be greater than a thickness TK22 of the mixed layer 35B. For example, the mixed layer 35B and the mixed layer 35C may be a compound of tantalum nitride and titanium nitride, and the chemical formula of this compound may be represented by TaₓTi_{y}N_{z}, but not limited thereto. In addition, the concentration of tantalum in the mixed layer 35B may be lower than the concentration of tantalum in the tantalum nitride barrier layer 34B, the concentration of tantalum in the mixed layer 35C may be lower than the concentration of tantalum in the tantalum nitride barrier layer 34C, and the tantalum atoms, the titanium atoms, and the nitrogen atoms may be substantially distributed evenly in the mixed layer 35B and the mixed layer 35C. In addition, in the gate structure GS1, the n-type work function layer 40A may directly contact the tantalum nitride barrier layer 34A, and there may be not any mixed layer described above located between the n-type work function layer 40A and the tantalum nitride barrier layer 34A.

In some embodiments, the p-type work function layer 36C may be sandwiched between the p-type work function layer 38C and the mixed layer 35C, and the p-type work function layer 36C and the p-type work function layer 38C may include the same p-type work function material or different p-type work function materials. For example, the p-type work function layer 36C and the p-type work function layer 38C may include a titanium nitride layer or other suitable p-type work function material layers. In some embodiments, a material composition of the n-type work function layer 40A, a material composition of the n-type work function layer 40B, and a material composition of the n-type work function layer 40C may be identical to one another (such as being formed an n-type work function material 40 both), but not limited thereto. For example, the n-type work function layer 40A, the n-type work function layer 40B, and the n-type work function layer 40C may include titanium aluminide (TiAl), tantalum aluminide (TaAl), tungsten aluminide (WA1) or other suitable electrically conductive work function materials. Additionally, the gate structure GS1, the gate structure GS2, and the gate structure GS3 may further include an electrically conductive layer 44A, an electrically conductive layer 44B, and an electrically conductive layer 44C, respectively. The electrically conductive layer 44A, the electrically conductive layer 44B, and the electrically conductive layer 44C may be respectively surrounded by the layers stacked in the gate structures described above in the horizontal directions. The electrically conductive layer 44A, the electrically conductive layer 44B, and the electrically conductive layer 44C may include metallic electrically conductive materials, such as tungsten, aluminum, copper, titanium aluminide, titanium, or other suitable electrically conductive materials with relatively low electrical resistivity. In some embodiments, the gate structure GS1, the gate structure GS2, and the gate structure GS3 may further include a top barrier layer 42A, a top barrier layer 42B, and a top barrier layer 42C, respectively, and each top barrier layer may be sandwiched between the corresponding n-type work function layer and the electrically conductive layer described above. The top barrier layer 42A, the top barrier layer 42B, and the top barrier layer 42C may include titanium nitride or other suitable electrically conductive barrier materials. Through the laminate design in each gate structure described above, the corresponding transistor may have the required operation performance and meet the product requirements.

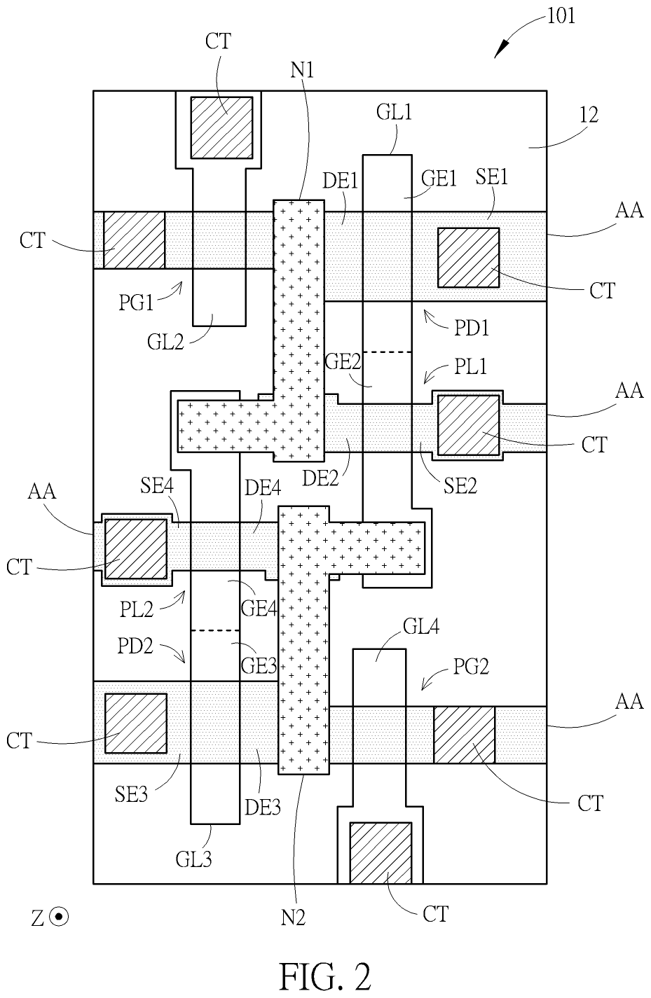

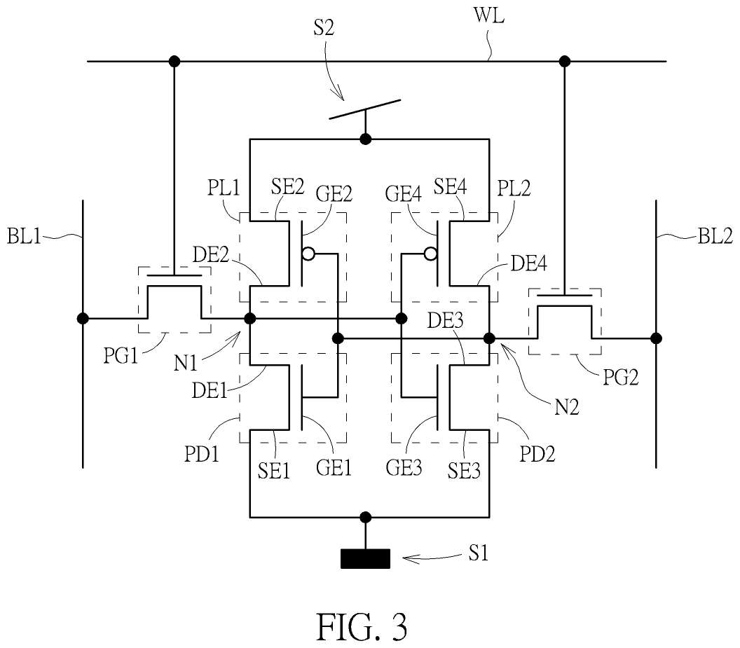

Please refer to FIGS. 1-3. FIG. 2 is a top view schematic drawing illustrating a static random access memory (SRAM) structure 101 according to an embodiment of the present invention, and FIG. 3 is a schematic circuit diagram of the static random access memory structure in this embodiment. As shown in FIG. 2 and FIG. 3, the static random access memory structure 101 in this embodiment may include a six-transistor SRAM (6T-SRAM) cell structure, but not limited thereto. For example, the static random access memory structure 101 may include a passing gate transistor PG1, a passing gate transistor PG2, a pull-down transistor PD1, a pull-down transistor PD2, a pull-up transistor PL1, and a pull-up transistor PL2. A source electrode SE1 of the pull-down transistor PD1 and a source electrode SE3 of the pull-down transistor PD2 are connected to a voltage source S1. A source electrode SE2 of the pull-up transistor PL1 and a source electrode SE4 of the pull-up transistor PL2 are connected to a voltage source S2. A drain electrode DE1 of the pull-down transistor PD1, a drain electrode DE2 of the pull-up transistor PL1, a gate electrode GE3 of the pull-down transistor PD2, and a gate electrode GE4 of the pull-up transistor PL2 are connected to a storage node N1. A drain electrode DE3 of the pull-down transistor PD2, a drain electrode DE4 of the pull-up transistor PL2, a gate electrode GE1 of the pull-down transistor PD1, and a gate electrode GE2 of the pull-up transistor PL1 are connected to a storage node N2. In some embodiments, the passing gate transistor PG1, the passing gate transistor PG2, the pull-down transistor PD1, and the pull-down transistor PD2 may be n-type field-effect transistors, and the pull-up transistor PL1 and the pull-up transistor PL2 may be p-type field-effect transistors. When the voltage source S1 is ground voltage and the voltage source S2 is supply voltage, the pull-down transistor PD1, the pull-down transistor PD2, the pull-up transistor PL1, and the pull-up transistor PL2 may constitute a latch that stores data in the storage node N1 or the storage node N2. In addition, a gate electrode, a source electrode, and a drain electrode of the passing gate transistor PG1 may be electrically connected to a word line WL, a bit line BL1 and the storage node N1, respectively, and a gate electrode, a source electrode, and a drain electrode of the passing gate transistor PG2 may be electrically connected to the word line WL, a bit line BL2 and the storage node N2, respectively. In some embodiments, the above-mentioned n-type transistor NT2 in FIG. 1 may be the passing gate transistor or the pull-down transistor in the static random access memory structure 101, and the above-mentioned p-type transistor PT in FIG. 1 may be the pull-up transistor in the static random access memory structure 101, but not limited thereto.

In some embodiments, a plurality of active regions AA separated from one another may be defined in the semiconductor substrate 10 by the isolation structure 12, and some of the active regions may be shared by the pull-down transistor and the passing gate transistor in the static random access memory structure 101, but not limited thereto. In the static random access memory structure 101, the gate electrode, the source electrode, and the drain electrode of the transistor may be electrically connected to the corresponding circuits via contact structures CT, and the gate electrodes of some transistors may be connected with each other and constitute a gate line. For example, a gate line GL1 may include the gate electrode GE1 of the pull-down transistor PD1 and the gate electrode GE2 of the pull-up transistor PL1 connected with each other, a gate line GL2 may include the gate electrode GE3 of the pull-down transistor PD2 and the gate electrode GE4 of the pull-up transistor PL2 connected with each other, and a gate line GL2 and a gate line GL4 may include the gate electrode of the passing gate transistor PG1 and the gate electrode of the passing gate transistor PG2, respectively. It is worth noting that, the static random access memory structure corresponding to the above-mentioned n-type transistor NT2 in FIG. 1 may include but is not limited to the condition illustrated in FIG. 2 and FIG. 3. In other words, the n-type transistor NT2 may also be applied in other suitable circuit structures according to some design considerations.

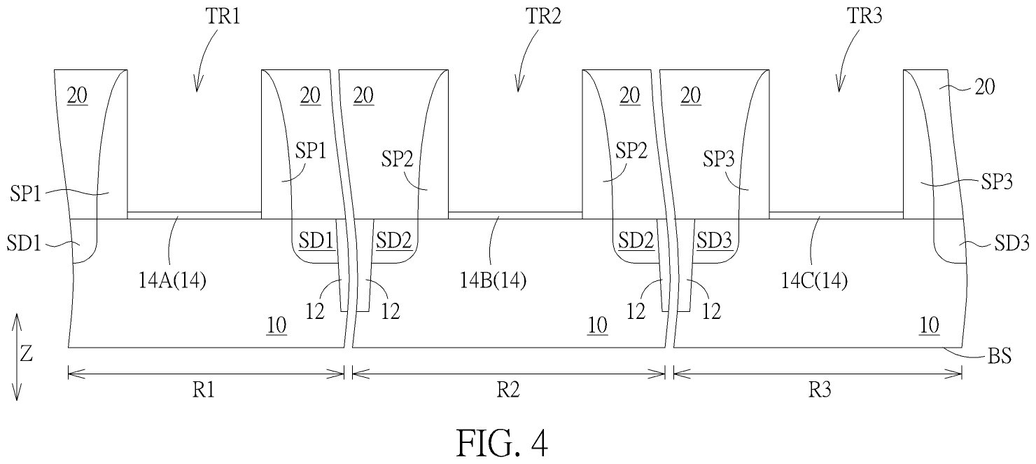

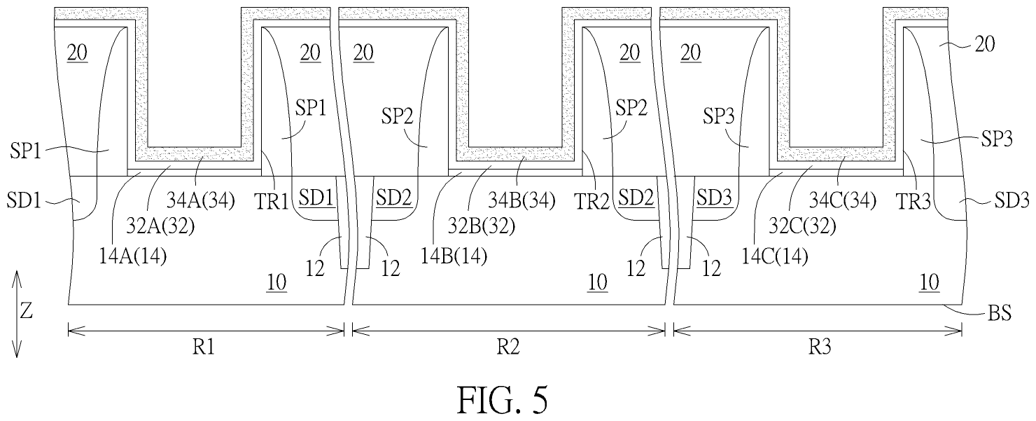

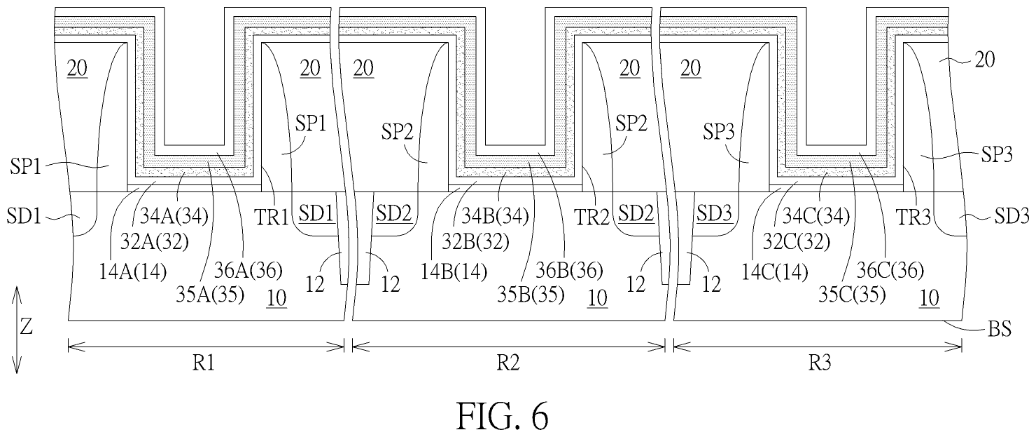

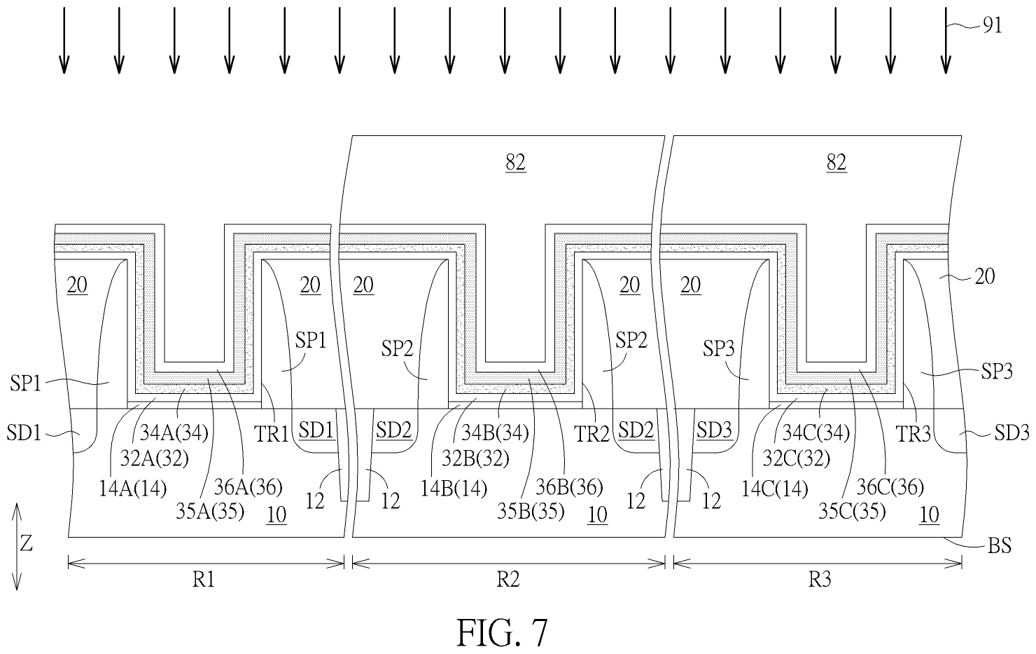

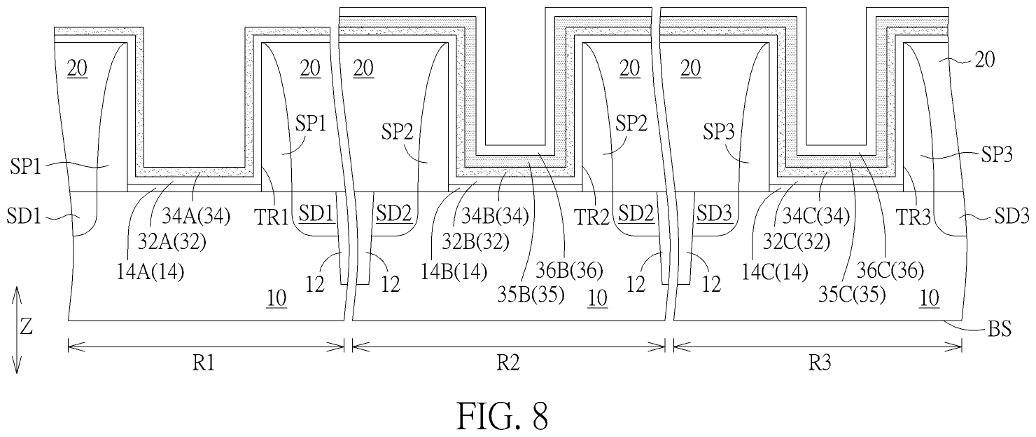

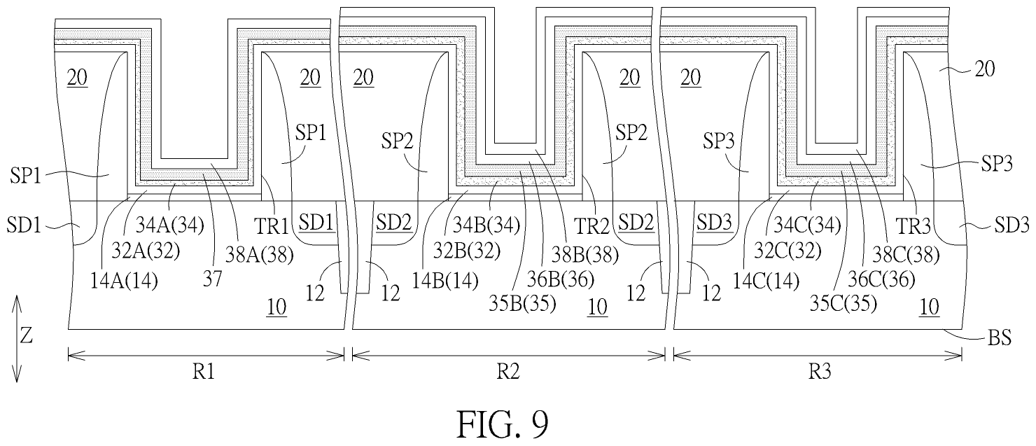

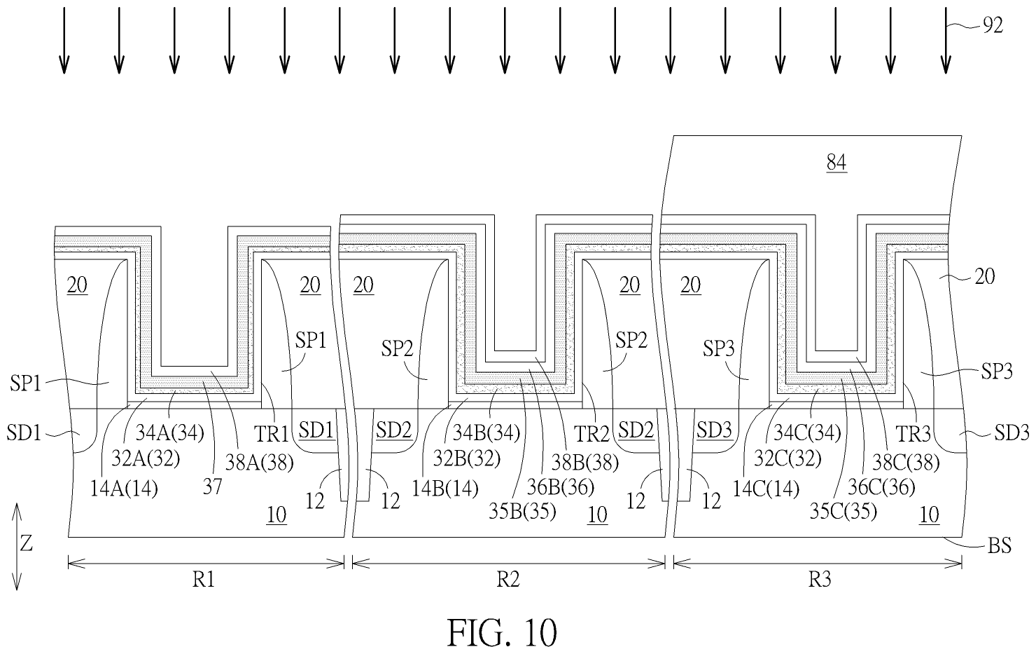

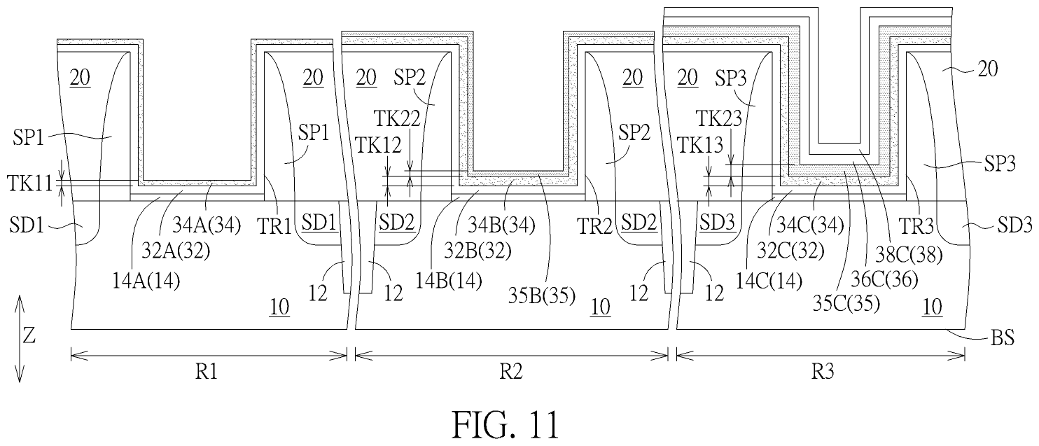

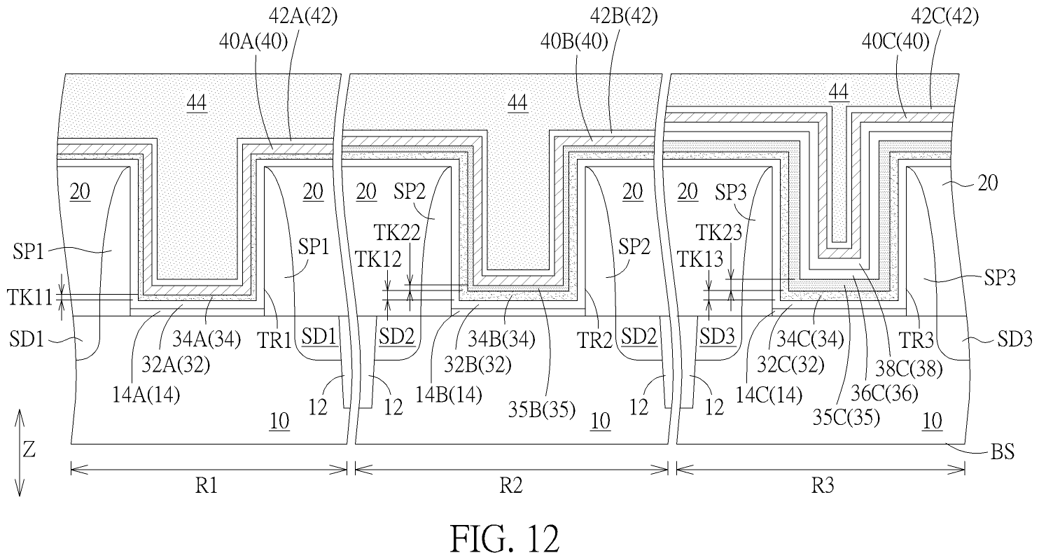

Please refer to FIG. 1 and FIGS. 4-12. FIGS. 4-12 are schematic drawings illustrating a manufacturing method of a semiconductor device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11. In some embodiments, FIG. 1 may be regarded as a schematic drawing in a step subsequent to FIG. 12, but not limited thereto. As shown in FIG. 1, the manufacturing method in this embodiment may include the following steps. Firstly, the semiconductor substrate 10 is provided. The semiconductor substrate 10 has a logic region (such as the first region R1) and a memory region (such as the second region R2). The n-type transistor NT1 is formed on the first region R1, and the n-type transistor NT2 is formed on the second region R2. The n-type transistor NT1 includes the gate structure GS1, the gate structure GS1 includes the tantalum nitride barrier layer 34A and the n-type work function layer 40A, and the n-type work function layer 40A is disposed on the tantalum nitride barrier layer 34A. The n-type transistor NT2 includes the gate structure GS2, the gate structure GS2 includes the tantalum nitride barrier layer 34B and the n-type work function layer 40B, and the n-type work function layer 40B is disposed on the tantalum nitride barrier layer 34B. The thickness TK11 of the tantalum nitride barrier layer 34A is less than the thickness TK12 of the tantalum nitride barrier layer 34B.

Specifically, the manufacturing method in this embodiment may include but is not limited to the following steps. As shown in FIG. 4, the semiconductor substrate 10 may include the first region R1, the second region R2, and the third region R3 described above. The isolation structure 12 may be formed in the semiconductor substrate 10, and the gate dielectric layer 14A, the gate dielectric layer 14B, and the gate dielectric layer 14C may be formed on the first region R1, the second region R2, and the third region R3, respectively. In some embodiments, dummy gate structures (not illustrated) may be formed correspondingly on the gate dielectric layer 14A, the gate dielectric layer 14B, and the gate dielectric layer 14C. The spacer structure SP1, the spacer structure SP2, and the spacer structure SP3 may be formed on the sidewalls of the corresponding dummy gate structures, respectively. The trench TR1, the trench TR2, and the trench TR3 described above may be formed by removing the dummy gate structures after the source/drain regions SD1, the source/drain regions SD2, the source/drain regions SD3, and the dielectric layer 20 are formed. Subsequently, as shown in FIG. 5, the titanium nitride barrier material 32 and the tantalum nitride barrier material 34 may be sequentially formed on the semiconductor substrate 10. The titanium nitride barrier material 32 may be formed conformally on the dielectric layer 20 and conformally in each trench, and the tantalum nitride barrier material 34 may be formed conformally on the titanium nitride barrier material 32. Each trench is not fully filled with the titanium nitride barrier material 32 and the tantalum nitride barrier material 34. The titanium nitride barrier material 32 and the tantalum nitride barrier material 34 may be partly formed in the trench TR1, partly formed in the trench TR2, and partly formed in the trench TR3. The titanium nitride barrier material 32 formed in the trench TR1, the trench TR2, and the trench TR3 may be regarded as the titanium nitride barrier layer 32A, the titanium nitride barrier layer 32B, and the titanium nitride barrier layer 32C described above, respectively. The tantalum nitride barrier material 34 formed in the trench TR1, the trench TR2, and the trench TR3 may be regarded as the tantalum nitride barrier layer 34A, the tantalum nitride barrier layer 34B, and the tantalum nitride barrier layer 34C described above, respectively.

As shown in FIG. 6, a first p-type work function material (such as a p-type work function material 36) may be formed on the tantalum nitride barrier material 34, and a first mixed material (such as a mixed material 35) may be formed between the p-type work function material 36 and the tantalum nitride barrier material 34. In some embodiments, the mixed material 35 may be regarded as a mixed layer formed by interdiffusion between the p-type work function material 36 and the tantalum nitride barrier material 34, and the mixed material 35 may include tantalum nitride and the element of the p-type work function material 36 accordingly. For example, the p-type work function material 36 may include a titanium nitride layer, and the mixed material 35 may be a compound of tantalum nitride and titanium nitride. The concentration of tantalum in the mixed material 35 may be lower than the concentration of tantalum in the tantalum nitride barrier material 34, and the concentration of titanium in the mixed material 35 may be lower than the concentration of titanium in the p-type work function material 36. In other words, a part of the tantalum nitride barrier material 34 may be consumed for forming the mixed material 35, and the thickness of the tantalum nitride barrier material 34 may be decreased because of the formation of the mixed material 35 accordingly. The p-type work function material 36 may be partly formed in the trench TR1, partly formed in the trench TR2, and partly formed in the trench TR3, and the mixed material 35 may be partly formed in the trench TR1, partly formed in the trench TR2, and partly formed in the trench TR3. The p-type work function material 36 located in the trench TR1, the trench TR2, and the trench TR3 may be regarded as a p-type work function layer 36A, a p-type work function layer 36B, and the p-type work function layer 36C, respectively. The mixed material 35 located in the trench TR1, the trench TR2, and the trench TR3 may be regarded as a mixed layer 35A, the mixed layer 35B, and the mixed layer 35C, respectively.

As shown in FIG. 7, a first mask layer (such as a mask layer 82) may be formed covering the p-type work function material 36 located above the second region R2 and the third region R3, and the p-type work function material 36 located above the first region R1 is not covered by the mask layer 82. Therefore, the mask layer 82 may cover the p-type work function material 36 located in the trench TR2 and the p-type work function material 36 located in the trench TR3, and the p-type work function material 36 located in the trench TR1 is not covered by the mask layer 82. In some embodiments, the mask layer 82 may include photoresist or other suitable mask materials. Subsequently, as shown in FIG. 7 and FIG. 8, a first removing process using the mask layer 82 as a mask (such as a removing process 91) may be performed, the first p-type work function material 36 in the trench TR1 (i.e. the p-type work function layer 36A) and the mixed material 35 in the trench TR1 (i.e. the mixed layer 35A) may be removed by the removing process 91, and the mask layer 82 may be removed after the removing process 91. Subsequently, after the mask layer 82 is removed, a second p-type work function material (such as a p-type work function material 38) may be formed on the semiconductor substrate 10 as shown in FIG. 9. The p-type work function material 38 may be partly formed on the tantalum nitride barrier material 34 located in the trench TR1, partly formed on the p-type work function material 36 located in the trench TR2, and partly formed on the p-type work function material 36 located in the trench TR3, and a second mixed material (such as a mixed material 37) may be formed between the p-type work function material 38 located in the trench TR1 and the tantalum nitride barrier material 34 located in the trench TR1.

In some embodiments, the mixed material 37 may be regarded as a mixed layer formed by interdiffusion between the p-type work function material 38 and the tantalum nitride barrier material 34, and the mixed material 37 may include tantalum nitride and the element of the p-type work function material 38 accordingly. For example, the p-type work function material 38 may include a titanium nitride layer, and the mixed material 37 may be a compound of tantalum nitride and titanium nitride. The concentration of tantalum in the mixed material 37 may be lower than the concentration of tantalum in the tantalum nitride barrier material 34, and the concentration of titanium in the mixed material 37 may be lower than the concentration of titanium in the p-type work function material 38. A part of the tantalum nitride barrier material 34 located in the trench TR1 may be consumed for forming the mixed material 37, and the thickness of the tantalum nitride barrier material 34 located in the trench TR1 may be decreased because of the formation of the mixed material 37 accordingly. Relatively, the tantalum nitride barrier material 34 located above the second region R2 and the third region R3 will not be influenced by the p-type work function material 38 because the tantalum nitride barrier material 34 located above the second region R2 and the third region R3 is covered by the p-type work function material 36. Therefore, under the situation illustrated in FIG. 9, the thickness of the tantalum nitride barrier material 34 located above the second region R2 and the third region R3 may be greater than the thickness of the tantalum nitride barrier material 34 located above the first region R1. In addition, the p-type work function material 38 located in the trench TR1, the trench TR2, and the trench TR3 may be regarded as a p-type work function layer 38A, a p-type work function layer 38B, and the p-type work function layer 38C, respectively. Subsequently, as shown in FIG. 10, a second mask layer (such as a mask layer 84) may be formed covering the p-type work function material 38 located above the third region R3, the mask layer 84 may cover the p-type work function material 38 located in the trench TR3 accordingly, and the p-type work function material 38 located in the trench TR1 and the trench TR2 are exposed. Subsequently, a second removing process using the mask layer 84 as a mask (such as a removing process 92) may be performed, the p-type work function material 38 located in the trench TR1 (i.e. the p-type work function layer 38A), the mixed material 37 in the trench TR1, the p-type work function material 38 in the trench TR2 (i.e. the p-type work function layer 38B), and the p-type work function material 36 in the trench TR2 (i.e. the p-type work function layer 36B) may be removed by the removing process 92.

In some embodiments, the removing process 91 illustrated in FIG. 7 and the removing process 92 illustrated in FIG. 10 may respectively include wet etching processes or other removing approaches with suitable selectivity, respectively. For example, a SC-2 clean process (a cleaning process using a mixed chemical solution of hydrogen chloride, hydrogen peroxide, and deionized water and called as a HPM cleaning process) with a higher etching rate to titanium nitride (such as 42 angstroms/min) and a lower etching rate to tantalum nitride (such as 1 angstrom/min) may be used as the removing process 91 and the removing process 92 described above, but not limited thereto. As shown in FIG. 10 and FIG. 11, the mask layer 84 may be removed after the removing process 92, and the mask layer 84 may include photoresist or other suitable mask materials. Additionally, in some embodiments, a part of the mixed material 35 located above the second region R2 (such as the mixed layer 35B) may be removed by the removing process 92, and the mixed material 35 located above the third region R3 (such as the mixed layer 35C) may be covered and protected by the mask layer 84 in the removing process 92. In other words, the mixed material 35 may remain in the trench TR2 and the trench TR3 after the removing process 92, the thickness of the mixed material 35 in the trench TR2 (such as the mixed layer 35B) may be reduced by the removing process 92, and a thickness of the mixed material 35 in the trench TR2 after the removing process 92 (such as the thickness TL12 of the mixed layer 35B) may be less than a thickness of the mixed material 35 in the trench TR2 after the removing process 92 (such as the thickness TK13 of the mixed layer 35C).

Subsequently, as shown in FIG. 12, the n-type work function material 40, a top barrier material 42, and an electrically conductive material 44 may be formed sequentially. The n-type work function material 40, the top barrier material 42, and the electrically conductive material 44 may be partly formed in the trench TR1, partly formed in the trench TR2, and partly formed in the trench TR3. The n-type work function material 40 located in the trench TR1, the trench TR2, and the trench TR3 may be regarded as the n-type work function layer 40A, the n-type work function layer 40B, and the n-type work function layer 40C, respectively. The top barrier material 42 located in the trench TR1, the trench TR2, and the trench TR3 may be regarded as the top barrier layer 42A, the top barrier layer 42B, and the top barrier layer 42C, respectively. The electrically conductive material 44 located in the trench TR1, the trench TR2, and the trench TR3 may be regarded as the electrically conductive layer 44A, the electrically conductive layer 44B, and the electrically conductive layer 44C illustrated in FIG. 1, respectively. Subsequently, the material layers located outside the trenches may be removed by a planarization process (such as a chemical mechanical polishing process, an etching back process, or other suitable planarization approaches) for forming the gate structure GS1, the gate structure GS2, and the gate structure GS3 illustrated in FIG. 1. Therefore, top surfaces of the materials layers in the gate structure GS1, the gate structure GS2, and the gate structure GS3 may be substantially coplanar, but not limited thereto. In some embodiments, the n-type work function layer 40A may be formed in the trench TR1 and directly contact the tantalum nitride barrier layer 34A, the n-type work function layer 40B may be formed in the trench TR2 and formed on the mixed material 35 in the trench TR2 (such as the mixed layer 35B), and the n-type work function layer 40C may be formed in the trench TR3 and formed on the p-type work function material 38 in the trench TR3 (such as the p-type work function layer 38C). Additionally, in some embodiments, the n-type work function layer 40A, the n-type work function layer 40B, and the n-type work function layer 40C may be formed concurrently by the same process after the second removing process (such as the removing process illustrated in FIG. 10), and the material compositions of the n-type work function layer 40A, the n-type work function layer 40B, and the n-type work function layer 40C may be identical to one another accordingly, but not limited thereto.

As shown in FIG. 1, the n-type transistor NT1, the n-type transistor NT2, and the p-type transistor PT may be formed on the semiconductor substrate 10 by the manufacturing method described above. The gate structure GS1 of the n-type transistor NT1 is formed in the trench TR1 located above the first region R1, the gate structure GS2 of the n-type transistor NT2 is formed in the trench TR2 located above the second region R2, and the gate structure GS3 of the p-type transistor PT is formed in the trench TR3 located above the third region R3. By the manufacturing method described above, the materials for forming the p-type work function layer in the p-type transistor PT may be formed by two steps and partially removed by two steps, and the thickness of the tantalum nitride barrier layer 34A in the n-type transistor NT1 may be reduced by the two removing processes. The thinner tantalum nitride barrier layer 34A may be used to reduce the threshold voltage of the n-type transistor NT1. Therefore, in the manufacturing method described above, other treatments for adjusting threshold voltage (such as an ion implantation process for adjusting threshold voltage, but not limited thereto) will not be required to be performed to the n-type transistor NT1 and/or the n-type transistor NT2 accordingly, and the electrical performance of the n-type transistor NT1 and the n-type transistor NT2 may be improved by avoiding negative influence cause by the other treatments. It is worth noting that, the method of forming the gate structure GS1, the gate structure GS2, and the gate structure GS3 may include but is not limited to the steps illustrated in FIGS. 4-12. In other words, the gate structure GS1, the gate structure GS2, and the gate structure GS3 illustrated in FIG. 1 may also be formed by other suitable approaches according to some design considerations.

To summarize the above descriptions, according to the semiconductor device and the manufacturing method thereof in the present invention, the thinner tantalum nitride barrier layer may be used to reduce the threshold voltage of the n-type transistor located on the logic region, and the negative influence cause by other treatments for adjusting threshold voltage may be avoided accordingly. Additionally, the method of forming the p-type work function layer and the method of partially removing the p-type work function layer may be modified for thinning the tantalum nitride barrier layer located on the logic region, and the manufacturing method of the transistor structures on different regions may be integrated accordingly.

Those skilled in the art will readily observe that numerous modifications and alterations of the device and method may be made while retaining the teachings of the invention.

Accordingly, the above disclosure should be construed as limited only by the metes and bounds of the appended claims.

What is claimed is:

1. A semiconductor device, comprising:
a semiconductor substrate having a logic region and a memory region;
a first n-type transistor disposed on the logic region, wherein the first n-type transistor comprises a first gate structure, and the first gate structure comprises:
a first tantalum nitride barrier layer; and
a first n-type work function layer disposed on the first tantalum nitride barrier layer; and
a second n-type transistor disposed on the memory region, wherein the second n-type transistor comprises a second gate structure, and the second gate structure comprises:
a second tantalum nitride barrier layer; and
a second n-type work function layer disposed on the second tantalum nitride barrier layer, wherein a thickness of the first tantalum nitride barrier layer is less than a thickness of the second tantalum nitride barrier layer.

2. The semiconductor device according to claim 1, wherein a material composition of the first n-type work function layer is identical to a material composition of the second n-type work function layer, and the first n-type work function layer directly contacts the first tantalum nitride barrier layer.

3. The semiconductor device according to claim 1, wherein the second gate structure further comprises a first mixed layer disposed between the second tantalum nitride barrier layer and the second n-type work function layer, and the first mixed layer is a compound of tantalum nitride and titanium nitride.

4. The semiconductor device according to claim 3, wherein the first mixed layer directly contacts the second tantalum nitride barrier layer and the second n-type work function layer.

5. The semiconductor device according to claim 1, further comprising:
a p-type transistor disposed on the semiconductor substrate, wherein the p-type transistor comprises a third gate structure, and the third gate structure comprises:
a third tantalum nitride barrier layer; and
a p-type work function layer disposed on the third tantalum nitride barrier layer, wherein a thickness of the third tantalum nitride barrier layer is greater than the thickness of the first tantalum nitride barrier layer.

6. The semiconductor device according to claim 5, wherein the p-type work function layer comprises a titanium nitride layer, the third gate structure further comprises a second mixed layer disposed between the third tantalum nitride barrier layer and the p-type work function layer, and the second mixed layer is a compound of tantalum nitride and titanium nitride.

7. The semiconductor device according to claim 6, wherein the second mixed layer directly contacts the third tantalum nitride barrier layer and the p-type work function layer.

8. The semiconductor device according to claim 6, wherein the second gate structure further comprises a first mixed layer disposed between the second tantalum nitride barrier layer and the second n-type work function layer, a material composition of the second mixed layer is identical to a material composition of the first mixed layer, and a thickness of the second mixed layer is greater than a thickness of the first mixed layer.

9. The semiconductor device according to claim 5, wherein the third gate structure further comprises a third n-type work function layer disposed on the p-type work function layer, and a material composition of the first n-type work function layer, a material composition of the second n-type work function layer, and a material composition of the third n-type work function layer are identical to one another.

10. The semiconductor device according to claim 1, wherein the second n-type transistor is a passing gate transistor or a pull-down transistor in a static random access memory structure.

11. A manufacturing method of a semiconductor device, comprising:
providing a semiconductor substrate having a logic region and a memory region;
forming a first n-type transistor on the logic region, wherein the first n-type transistor comprises
a first gate structure, and the first gate structure comprises:
a first tantalum nitride barrier layer; and
a first n-type work function layer disposed on the first tantalum nitride barrier layer; and
forming a second n-type transistor on the memory region, wherein the second n-type transistor comprises a second gate structure, and the second gate structure comprises:
a second tantalum nitride barrier layer; and
a second n-type work function layer disposed on the second tantalum nitride barrier layer, wherein a thickness of the first tantalum nitride barrier layer is less than a thickness of the second tantalum nitride barrier layer.

12. The manufacturing method of the semiconductor device according to claim 11, wherein the first gate structure is formed in a first trench located above the logic region, the second gate structure is formed in a second trench located above the memory region, and the manufacturing method of the semiconductor device further comprises:
forming a p-type transistor on the semiconductor substrate, wherein the p-type transistor comprises a third gate structure disposed in a third trench located above the semiconductor substrate, and the third gate structure comprises:
a third tantalum nitride barrier layer, wherein a thickness of the third tantalum nitride barrier layer is greater than the thickness of the first tantalum nitride barrier layer.

13. The manufacturing method of the semiconductor device according to claim 12, wherein a method of forming the first gate structure, the second gate structure, and the third gate structure comprises:
forming a tantalum nitride barrier material on the semiconductor substrate, wherein the tantalum nitride barrier material is partly formed in the first trench, partly formed in the second trench, and partly formed in the third trench;
forming a first p-type work function material on the tantalum nitride barrier material, wherein the first p-type work function material is partly formed in the first trench, partly formed in the second trench, and partly formed in the third trench, a first mixed material is formed between the tantalum nitride barrier material and the first p-type work function material, and the first mixed material is partly formed in the first trench, partly formed in the second trench, and partly formed in the third trench;
forming a first mask layer covering the first p-type work function material in the second trench and the first p-type work function material in the third trench; and
performing a first removing process using the first mask layer as a mask, wherein the first p-type work function material in the first trench and the first mixed material in the first trench are removed by the first removing process.

14. The manufacturing method of the semiconductor device according to claim 13, wherein the first p-type work function material comprises a titanium nitride layer, and the first mixed material is a compound of tantalum nitride and titanium nitride.

15. The manufacturing method of the semiconductor device according to claim 13, wherein the method of forming the first gate structure, the second gate structure, and the third gate structure further comprises:
removing the first mask layer after the first removing process;
forming a second p-type work function material on the semiconductor substrate after the first mask layer is removed, wherein the second p-type work function material is partly formed on the tantalum nitride barrier material located in the first trench, partly formed on the first p-type work function material located in the second trench, and partly formed on the first p-type work function material located in the third trench, and a second mixed material is formed between the second p-type work function material located in the first trench and the tantalum nitride barrier material located in the first trench;
forming a second mask layer covering the second p-type work function material in the third trench; and
performing a second removing process using the second mask layer as a mask, wherein the second p-type work function material in the first trench, the second mixed material in the first trench, the second p-type work function material in the second trench, and the first p-type work function material in the second trench are removed by the second removing process.

16. The manufacturing method of the semiconductor device according to claim 15, wherein the first removing process and the second removing process comprise wet etching processes, respectively.

17. The manufacturing method of the semiconductor device according to claim 15, wherein the second p-type work function material comprises a titanium nitride layer, and the second mixed material is a compound of tantalum nitride and titanium nitride.

18. The manufacturing method of the semiconductor device according to claim 15, wherein a part of the tantalum nitride barrier material located in the first trench is consumed for forming the second mixed material, and a thickness of the tantalum nitride barrier material in the first trench is reduced because of the formation of the second mixed material.

19. The manufacturing method of the semiconductor device according to claim 15, wherein the first mixed material remains in the second trench and the third trench after the second removing process, a thickness of the first mixed material in the second trench is reduced by the second removing process, and the thickness of the first mixed material in the second trench after the second removing process is less than a thickness of the first mixed material in the third trench after the second removing process.

20. The manufacturing method of the semiconductor device according to claim 15, wherein the method of forming the first gate structure, the second gate structure, and the third gate structure further comprises:
forming the first n-type work function layer in the first trench, wherein the first n-type work function layer directly contacts the first tantalum nitride barrier layer;
forming the second n-type work function layer in the second trench, wherein the second n-type work function layer is formed on the first mixed material in the second trench; and
forming a third n-type work function layer in the third trench, wherein the third n-type work function layer is formed on the second p-type work function material in the third trench, and the first n-type work function layer, the second n-type work function layer, and the third n-type work function layer are formed concurrently by the same process after the second removing process.
